(19) United States
(12) Patent Application Publication
(10) Pub. No.: US 2014/0017903 A1
(43) Pub. Date: Jan. 16, 2014

(54) METHODS FOR FABRICATING INTEGRATED CIRCUITS WITH STRESSED SEMICONDUCTOR MATERIAL

(71) Applicants: Abner Bello, Troy, NY (US); Abhijeet Paul, Albany, NY (US)

(72) Inventors: Abner Bello, Troy, NY (US); Abhijeet Paul, Albany, NY (US)

(73) Assignee: GLOBALFOUNDRIES INC., Grand Cayman (KY)

(21) Appl. No.: 13/545,646

(22) Filed: Jul. 10, 2012

(51) Int. Cl. H01L 21/304; H01L 21/31

(52) U.S. Cl. 438/758; 438/800; 257/E21.237; 257/E21.24

(57) ABSTRACT

Methods for fabricating integrated circuits are provided. In an embodiment, a method for fabricating an integrated circuit includes providing a semiconductor substrate having a first surface. In the method, a stress is applied to the semiconductor substrate to change inter-atomic spacing at the first surface of the semiconductor substrate to a stressed inter-atomic spacing. Then, the semiconductor substrate is processed. Thereafter, the stress is released and the first surface of the processed semiconductor substrate retains the stressed inter-atomic spacing.

TECHNICAL FIELD

The present disclosure generally relates to methods for fabricating integrated circuits, and more particularly relates to methods for fabricating integrated circuits with stressed semiconductor material.

### BACKGROUND

The majority of present day integrated circuits (ICs) are implemented by using a plurality of interconnected field effect transistors (FETs), also called metal oxide semiconductor field effect transistors (MOSFETs), or simply MOS transistors. Such transistors may be planar or non-planar, such as finFETS. A transistor includes a gate electrode as a control electrode, and a pair of spaced apart source and drain electrodes. A control voltage applied to the gate electrode controls the flow of a drive current through a channel that is established between the source and drain electrodes.

The complexity of ICs and the number of devices incorporated in ICs are continually increasing. As the number of devices in an IC increases, the size of individual devices decreases. Device size in an IC is usually noted by the minimum feature size; that is, the minimum line width or the minimum spacing that is allowed by the circuit design rules. As the semiconductor industry moves to smaller minimum feature sizes, the gain of performance due to scaling becomes limited. As new generations of integrated circuits and the MOS transistors that are used to implement those ICs are designed, technologists must rely heavily on non- conventional elements to boost device performance.

The performance of a MOS transistor, as measured by its current carrying capability, is proportional to the mobility of a majority carrier in the transistor's channel. By applying an appropriate stress to the channel of the MOS transistor, the mobility of the majority carrier in the channel can be increased which increases drive current thereby improving performance of the MOS transistor. For example, applying a compressive stress to the channel of a P-channel MOS (PMOS) transistor enhances the mobility of majority carrier holes, whereas applying a tensile stress to the channel of an N-channel MOS (NMOS) transistor enhances the mobility of majority carrier electrons. The known stress engineering methods greatly enhance circuit performance by increasing device drive current without increasing device size and device capacitance.

Accordingly, it is desirable to provide improved methods for fabricating integrated circuits with stressed semiconductor material. Furthermore, other desirable features and characteristics of the present invention will become apparent from the subsequent detailed description and the appended claims, taken in conjunction with the accompanying drawings and the foregoing technical field and background.

### BRIEF SUMMARY

Methods for fabricating integrated circuits are provided. In accordance with one embodiment, a method for fabricating an integrated circuit includes providing a semiconductor substrate having a first surface. In the method, a stress is applied to the semiconductor substrate to change inter-atomic spacing at the first surface of the semiconductor substrate to a stressed inter-atomic spacing. Then, the semiconductor substrate is processed. Thereafter, the stress is released and the first surface of the processed semiconductor substrate retains the stressed inter-atomic spacing.

In another embodiment, a method for stressing a semiconductor substrate for fabrication of an integrated circuit is provided. The method includes applying a stress throughout the semiconductor substrate. While applying the stress throughout the semiconductor substrate, a stress retention layer is formed over the semiconductor substrate. Then, the stress is released.

In accordance with another embodiment, a method for fabricating an integrated circuit provides a semiconductor substrate. A stress is applied to the semiconductor substrate to impose a stressed inter-atomic spacing therein. While applying the stress, a liner is formed over the semiconductor substrate. Then, the stress is released and the semiconductor substrate retains the stressed inter-atomic spacing through interaction with the liner.

### BRIEF DESCRIPTION OF THE DRAWINGS

Embodiments of methods for fabricating integrated circuits with stressed semiconductor material will hereinafter be described in conjunction with the following drawing figures, wherein like numerals denote like elements, and wherein:

FIGS. 1-6 illustrate, in cross section, a portion of an integrated circuit and method steps for fabricating an integrated circuit in accordance with various embodiments herein.

### DETAILED DESCRIPTION

The following detailed description is merely exemplary in nature and is not intended to limit the methods for fabricating integrated circuits as claimed herein. Furthermore, there is no intention to be bound by any expressed or implied theory presented in the preceding technical field, background or brief summary, or in the following detailed description.

In accordance with the various embodiments herein, methods for fabricating integrated circuits with stressed semiconductor material are provided. The methods described herein reduce or inhibit problems with conventional processes for stressing semiconductor material. For example, it has been found that, in conventional processing, carrier mobility gains afforded by the formation of stress layers on or within semiconductor material can be lost due to subsequent processing, such as film deposition, annealing, or etching. As contemplated herein, the semiconductor material is stressed during processing. As a result, the semiconductor material is more resilient to loss of stress forces. Further, the processing itself can result in stress memorization.

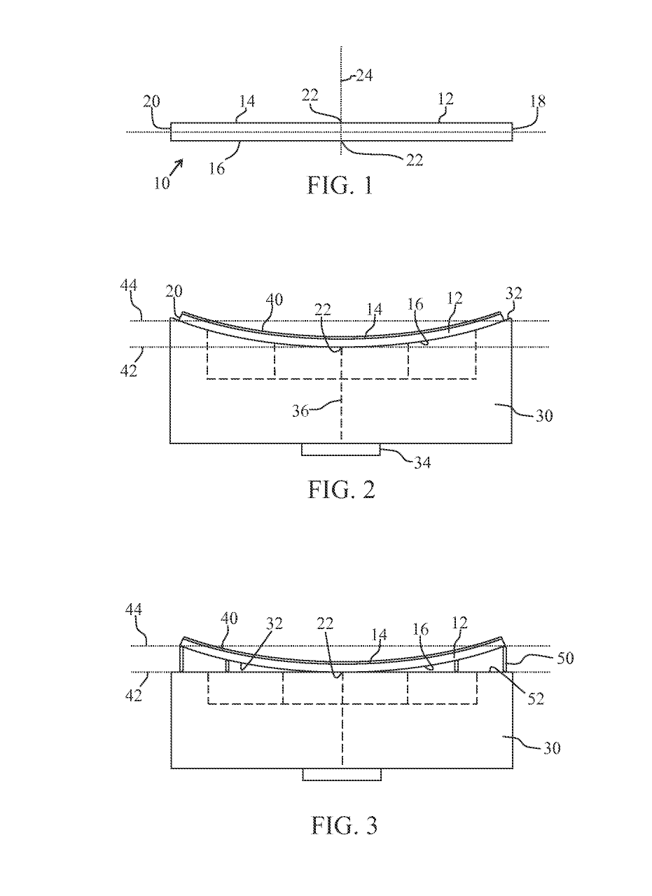

FIGS. 1-6 illustrate steps in accordance with various embodiments of methods for fabricating integrated circuits. Various steps in the design and composition of integrated circuits are well known and so, in the interest of brevity, many conventional steps will only be mentioned briefly herein or will be omitted entirely without providing the well known process details. Further, it is noted that integrated circuits include a varying number of components and that single components shown in the illustrations may be representative of multiple components.

In FIG. 1, in an exemplary embodiment, the process of fabricating an integrated circuit 10 (shown at the initial fabrication step) begins by providing a semiconductor substrate 12. The semiconductor substrate 12 may be a bulk silicon or silicon-on-insulator (SOI) wafer including a silicon-containing material layer overlying a silicon oxide layer. The semiconductor substrate 12 may be formed of relatively pure silicon materials typically used in the semiconductor industry as well as silicon admixed with other elements. Alternatively, the semiconductor substrate 12 can be realized as germanium, gallium arsenide, and the like, or the semiconductor substrate 12 can include layers of different semiconductor materials.

Typically, the semiconductor substrate 12 is a substantially circular wafer with a first surface 14 and a second surface 16 parallel to a radial plane 18 and extending to a periphery 20. Each surface 14, 16 has a center 22 located at the intersection of a central axis 24 and the respective surface 14, 16. As illustrated in FIG. 1, the semiconductor substrate 12 is substantially flat, as initially formed. At the atomic level, its semiconductor material atoms may be considered to be unstressed and have an initial unstressed inter-atomic spacing.

In FIG. 2, the semiconductor substrate 12 is positioned on a chuck 30. The chuck 30 includes a support surface 32 for receiving the second surface 16 of the semiconductor substrate 12. The support surface 32 is selectively shaped to impart a stress on the semiconductor substrate 12. As illustrated in FIG. 2, the support surface 32 is concave. As a result, the atoms at or near the first surface 14 of the semiconductor substrate 12 are forced toward one another—creating a stressed (compressed) inter-atomic spacing in the semiconductor substrate 12 at and near its first surface 14. In certain embodiments, the support surface 32 is spherically concave, i.e., curvilinear in all radial directions, in other embodiments the support surface 32 is cylindrically concave, i.e., curvilinear along a single radial plane.

An exemplary embodiment of the chuck 30 provides for pulling the semiconductor substrate 12 into full engagement with the support surface 32. For example, the semiconductor substrate 12, while somewhat flexible, may rest at its periphery 20 on support surface 32 without contact between the support surface 32 and the rest of the semiconductor substrate 12. Thus, the chuck 30 may need to apply a force to fully engage the center 22 of the second surface 16 of the semiconductor substrate 12 with the support surface 32. For that reason, the exemplary chuck 30 is provided with and in communication with a vacuum source 34. Further, the chuck 30 may be porous such that the vacuum source 34 can apply a negative pressure or vacuum force at the support surface 32. Alternatively, the chuck 30 may include conduits 36 in communication with the support surface 32 to apply the negative pressure or vacuum force to the semiconductor substrate 12.

With the semiconductor substrate 12 being stressed and its first surface 14 being maintained with a compressed inter-atomic spacing, the semiconductor substrate 12 is processed. For example, the semiconductor substrate 12 may have a layer or layers formed thereon, be thermally treated or annealed, be etched, or a combination thereof. In FIG. 2, a stress retention liner 40 is formed on the first surface 14 of the semiconductor substrate. By way of example, the stress retention liner 40 may be deposited titanium nitride, deposited amorphous silicon, epitaxially grown silicon, or other thin film.

In FIG. 2, the center 22 of the second surface 16 of the semiconductor substrate 12 is supported by the support surface 32 of the chuck 30 at a center plane 42 that is substantially tangential to the second surface 16 of the semiconductor substrate 12. Further, the periphery 20 of the second surface 16 of the semiconductor substrate 12 is supported by the support surface 32 of the chuck 30 at a periphery plane 44 parallel to the center plane 42. The distance between the center plane 42 and the periphery plane 44 (or relative height) is determined by the curvature of the support surface 32 of the chuck 30. The relative height, and curvature, can be selected in view of the radius of the semiconductor substrate 12 and the desired stress to be imposed. Using Stoney's formula, it is known that the receiving surface curvature is inversely proportional to the stress applied to the semiconductor substrate 12:

$${σ}^{( f )} = \frac{{E}_{s} {h}_{s}^{2} κ}{6 {h}_{f} ( 1 - {v}_{s} )}$$

wherein subscript f denotes the film or liner 40, subscript s denotes the substrate 12, h is layer thickness, K is the curvature of the film, E is the Young's modulus, and v is the Poisson's ratio. For a typical semiconductor substrate 12 having a radius of about 150 millimeters (mm) and formed with a titanium nitride liner 40, a relative height of no more than about 0.3 mm is sufficient to impose a stress of about 20 gigapascals (GPa).

FIG. 3 illustrates an alternate embodiment of the chuck 30 for applying a compressive stress on the first surface 14 of the semiconductor substrate 12. In FIG. 3, the chuck 30 includes an adjustable support surface 32 that is formed by movable extensions or pins 50. The pins 50 are extendable from a surface 52 formed by the chuck 30. As shown, a plurality of pins 50 may be utilized to position the semiconductor substrate 12 at a desired curvature, i.e., with a desired relative height between planes 42 and 44. While, as illustrated, the center 22 of the second surface 16 of the semiconductor substrate 12 rests on the surface 52, it is contemplated that the entire semiconductor substrate 12 could be supported by pins 50. Again, negative pressure or vacuum force may be applied to pull the semiconductor substrate 12 toward the support surface 32. Further, the pins 50 may be selectively moved to push the periphery 20 of the semiconductor substrate 12 away from the chuck 30. In any event, the semiconductor substrate 12 is positioned as desired to apply the compressive stress on the first surface 14. As noted above, the support surface 32 may be spherically concave, i.e., curvilinear in all radial directions, or cylindrically concave, i.e., curvilinear in the direction of a single radial plane. Then, the semiconductor substrate 12 is processed. In FIG. 3, the processing includes forming a liner 40 on the first surface 14 of the semiconductor substrate 12.

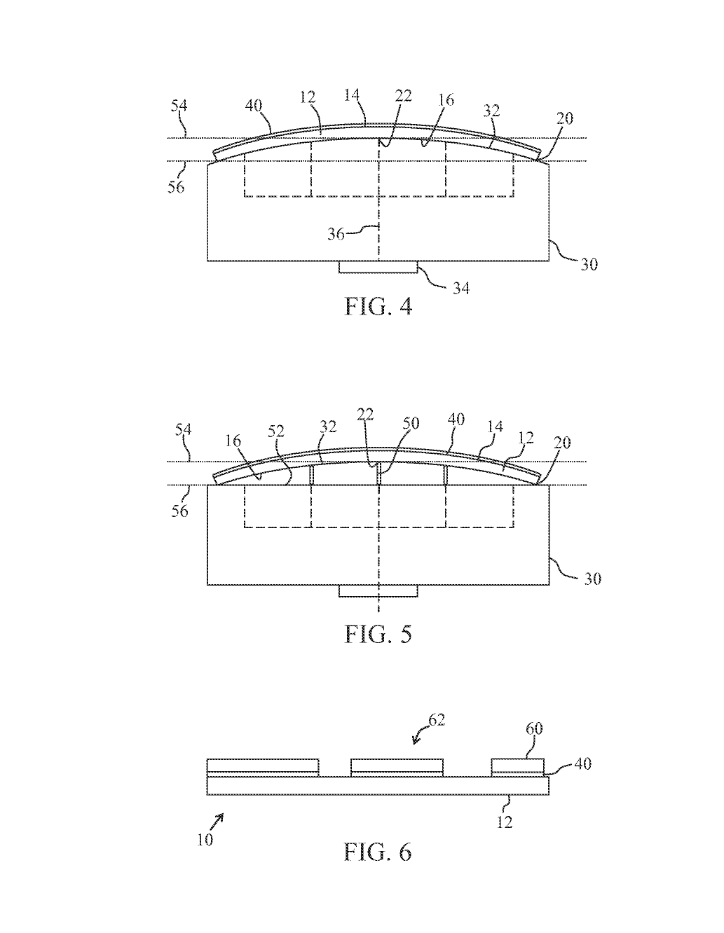

FIG. 4 shows a chuck 30 for applying a tensile stress to the first surface 14 of the semiconductor substrate 12. As illustrated, the chuck 30 includes a convex support surface 32 for receiving the second surface 16 of the semiconductor substrate 12. As a result, the atoms at or near the first surface 14 of the semiconductor substrate 12 are pulled away from one another —creating a stressed (expanded) inter-atomic spacing in the semiconductor substrate 12 at and near its first surface 14. In certain embodiments, the support surface 32 is spherically convex, i.e., curvilinear in all radial directions, in other embodiments the support surface 32 is cylindrically concave, i.e., curvilinear in the direction of a single radial plane.

Again, the chuck 30 provides for pulling the semiconductor substrate 12 into full engagement with the support surface 32. For example, on convex chuck 30 the semiconductor substrate 12 may rest at its center 22 on support surface 32 without contact between the support surface 32 and the rest of the semiconductor substrate 12. Thus, the chuck 30 may need to apply a force to fully engage the periphery 20 of the second surface 16 of the semiconductor substrate 12 with the support surface 32. For that reason, the exemplary chuck 30 is provided with and in communication with vacuum source 34. Again, it is contemplated that the chuck 30 be porous and/or include conduits 36 in communication with the support surface 32 to apply the negative pressure or vacuum force to the semiconductor substrate 12.

With the semiconductor substrate 12 in FIG. 4 being stressed and its first surface 14 being maintained with an expanded inter-atomic spacing, the semiconductor substrate 12 is processed. For example, the semiconductor substrate 12 may have a layer or layers formed thereon, be thermally treated or annealed, be etched, or a combination thereof. In FIG. 4, a stress retention liner 40 is formed on the first surface 14 of the semiconductor substrate. By way of example, the stress retention liner 40 may be deposited titanium nitride, deposited amorphous silicon, epitaxially grown silicon, or other thin film.

In FIG. 4, the center 22 of the second surface 16 of the semiconductor substrate 12 is supported by the support surface 32 of the chuck 30 at a center plane 54 that intersects the semiconductor substrate 12. Further, the periphery 20 of the second surface 16 of the semiconductor substrate 12 is supported by the support surface 32 of the chuck 30 at a periphery plane 56 parallel to the center plane 54. As with respect to the concave embodiment, the distance between the center plane 54 and the periphery plane 56 (or relative height) is determined by the curvature of the support surface 32 of the chuck 30. The relative height, and curvature, are again selected in view of the radius of the semiconductor substrate 12 and the desired stress to be imposed and using Stoney's formula.

FIG. 5 illustrates an alternate embodiment of the chuck 30 for applying a tensile stress on the first surface 14 of the semiconductor substrate 12. Identical to the embodiment of FIG. 3, the chuck 30 includes an adjustable support surface 32 that is formed by movable extensions or pins 50. The pins 50 are extendable from a surface 52 formed by the chuck 30. As shown, a plurality of pins 50 may be utilized to position the semiconductor substrate 12 at a desired curvature, i.e., with a desired relative height between planes 54 and 56. While, as illustrated, the periphery 20 of the second surface 16 of the semiconductor substrate 12 rests on the surface 52, it is contemplated that the entire semiconductor substrate 12 could be supported by pins 50. Again, negative pressure or vacuum force may be applied to pull the semiconductor substrate 12 toward the support surface 32. Further, the pins 50 may be selectively moved to push the center 22 of the semiconductor substrate 12 away from the chuck 30. In any event, the semiconductor substrate 12 is positioned as desired to apply the tensile stress on the first surface 14. Then, the semiconductor substrate 12 is processed. For the processing illustrated in FIG. 5, a liner 40 is formed on the first surface 14 of the semiconductor substrate 12. As noted above, the support surface 32 may be spherically convex, i.e., curvilinear in all radial directions, or cylindrically convex, i.e., curvilinear in the direction of a single radial plane.

FIG. 6 illustrates a partially fabricated integrated circuit 10 after the stress is released and further processing has been performed. The partially fabricated integrated circuit 10 may have resulted from stress application of any of FIG. 2, 3, 4 or 5. As shown in FIG. 6, in an exemplary process, the semiconductor substrate returns to its flat configuration, an additional layer 60 is selectively deposited or grown over the liner 40, and each is etched to form the structures 62 on semiconductor substrate 12. Additional processing forming gate structures and transistor structures (e.g., front end of line (FEOL) process steps) and well known final process steps (e.g., back end of line (BEOL) process steps) may then be performed. It should be understood that various steps and structures may be utilized in further processing, and the subject matter described herein is not limited to any particular number, combination, or arrangement of steps or structures. Further, it is contemplated that the transistor structures on the stressed semiconductor substrate be formed in planar or non-planar device designs, including finFETS. Importantly, the post-stress process steps do not substantially affect the stress imposed in the semiconductor substrate 12, such that the stressed inter-atomic spacing remains substantially unchanged after processing.

As described above, fabrication processes are implemented to form integrated circuits with stressed semiconductor material. Stresses applied through conventional processes are frequently undone or impaired by later processing. Deleterious effects of later processing are reduced herein through the application of stress over the entire semiconductor substrate during processing. Specifically, the semiconductor substrate is subjected to a constant selected stress during processing such as liner formation, etching, and annealing. As a result, stresses imposed during processing are not released despite releasing the external stress on the semiconductor substrate. Further, the disclosed methods do not require additional deposition, patterning or etching steps.

To briefly summarize, the fabrication methods described herein result in integrated circuits with improved stressing of semiconductor material, and, as a result, increased carrier mobility. While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

1. A method for fabricating an integrated circuit comprising:
providing a semiconductor substrate having a first surface and a second surface;
locating the second surface of the semiconductor substrate on a selectively shaped surface of a chuck and applying a negative pressure to the second surface of the semiconductor substrate to apply a stress to the semiconductor substrate to change inter-atomic spacing at the first surface of the semiconductor substrate to a stressed inter-atomic spacing;
processing the semiconductor substrate; and
releasing the stress, wherein the first surface of the processed semiconductor substrate retains the stressed inter-atomic spacing after releasing the stress.

2. The method of claim 1 wherein applying a negative pressure to the second surface of the semiconductor substrate comprises applying a compressive stress to the first surface of the semiconductor substrate, and wherein the stressed inter-atomic spacing is a compressed inter-atomic spacing.

3. The method of claim 2 wherein the locating the second surface of the semiconductor substrate on a selectively shaped surface of a chuck comprises locating the second surface of the semiconductor substrate on a concave surface of the chuck.

4. The method of claim 2 wherein the a second surface has a center and a periphery, and wherein locating the second surface of the semiconductor substrate on a selectively shaped surface of a chuck comprises supporting the center of the second surface of the semiconductor substrate at a center plane and supporting the periphery of the second surface at a periphery plane parallel to the center plane, wherein the center plane is tangential to the semiconductor substrate.

5. The method of claim 1 wherein the chuck is porous and wherein applying a negative pressure to the second surface of the semiconductor substrate comprises applying a negative pressure to the second surface of the semiconductor substrate through the porous chuck.

6. The method of claim 1 wherein the chuck is provided with conduits in communication with a vacuum source, and wherein applying a negative pressure to the second surface of the semiconductor substrate comprises applying a negative pressure to the second surface of the semiconductor substrate from the vacuum source through the conduits in the chuck.

7. The method of claim 1 wherein locating the second surface of the semiconductor substrate on a selectively shaped surface of a chuck comprises applying a tensile stress to the first surface of the semiconductor substrate, and wherein the stressed inter-atomic spacing is an expanded inter-atomic spacing.

8. The method of claim 7 wherein applying a tensile stress to the first surface of the semiconductor substrate comprises locating the second surface of the semiconductor substrate on a convex surface of the chuck.

9. The method of claim 7 second surface has a center and a periphery, and wherein applying a tensile stress to the first surface of the semiconductor substrate comprises supporting the center of the second surface of the semiconductor substrate at a center plane and supporting the periphery of the second surface at a periphery plane parallel to the center plane, wherein the center plane intersects the semiconductor substrate.

10. The method of claim 9 wherein applying a tensile stress to the first surface of the semiconductor substrate comprises pushing the center of the second surface of the semiconductor to the center plane and supporting the periphery of the second surface at the periphery plane.

11. The method of claim 9 applying a tensile stress to the first surface of the semiconductor substrate comprises supporting the center of the second surface of the semiconductor substrate at the center plane and pulling the periphery of the second surface to the periphery plane.

12. The method of claim 1 wherein locating the second surface of the semiconductor substrate on a selectively shaped surface of a chuck comprises mechanically stressing the semiconductor substrate.

13. A method for stressing a semiconductor substrate for fabrication of an integrated circuit comprising:
applying a stress throughout the semiconductor substrate by applying a negative pressure from a vacuum source to a bottom surface of the semiconductor substrate;
while applying the stress throughout the semiconductor substrate, forming a stress retention layer over a top surface of the semiconductor substrate; and
releasing the stress.

14. The method of claim 13 wherein applying a stress throughout the semiconductor substrate comprises locating the bottom surface of the semiconductor substrate on the selectively shaped porous chuck, and applying negative pressure from the vacuum source to the bottom surface through the selectively shaped porous chuck.

15. The method of claim 13 wherein applying a stress throughout the semiconductor substrate comprises imposing mechanical stress on the semiconductor substrate with a selectively shaped chuck by locating the bottom surface of the semiconductor substrate on the selectively shaped chuck, and applying negative pressure from the vacuum source to the bottom surface through the selectively shaped chuck.

16. The method of claim 13 wherein the semiconductor substrate has a center and a periphery, and wherein applying a stress throughout the semiconductor substrate comprises supporting the center of the semiconductor substrate at a center plane and supporting the periphery of the semiconductor substrate at a periphery plane, wherein the center plane and the periphery plane are parallel.

17. A method for fabricating an integrated circuit comprising:
providing a semiconductor substrate having a top surface and a bottom surface;
locating the bottom surface of the semiconductor substrate on a selectively shaped surface of a chuck and applying a negative pressure from a vacuum source through the selectively shaped surface to the second surface of the semiconductor substrate to impose a stressed inter-atomic spacing therein;
while applying the stress, forming a liner over the semiconductor substrate; and
releasing the stress, wherein the semiconductor substrate retains the stressed inter-atomic spacing through interaction with the liner.

18. The method of claim 17 wherein the chuck is porous and applying a negative pressure from a vacuum source comprises applying the negative pressure through the porous chuck.

19. The method of claim 17 wherein the selectively shaped surface is concave and wherein the stressed inter-atomic spacing is a compressed inter-atomic spacing at the top surface.

20. The method of claim 17 wherein the selectively shaped surface is concave and wherein the stressed inter-atomic spacing is an expanded inter-atomic spacing at the top surface.
